(19) United States
(12) Patent Application Publication
(10) Pub. No.: US 2008/0048289 A1
(43) Pub. Date: Feb. 28, 2008

(54) RF Inductor of Semiconductor Device and Fabrication Method Thereof

(76) Inventor: HAN CHOON LEE, Songpa-go (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/845,954

(22) Filed: Aug. 28, 2007

(30) Foreign Application Priority Data
Aug. 28, 2006 (KR) 10-2006-0081967

(51) Int. Cl. H01L 29/00; H01L 21/00

(52) U.S. Cl. 257/531; 438/381; 257/E29.001

(57) ABSTRACT

An RF inductor of a semiconductor device and a method of fabricating the same are provided. First and second interlayer dielectric layers are formed on an insulating layer and a lower metal interconnection. A via hole and a spiral-shaped trench are formed in the first and second interlayer dielectric layers. A TiSiN layer is formed on the inner wall of the trench, and a copper interconnection is formed in the trench.

### CROSS-REFERENCE TO RELATED APPLICATION

The present application claims the benefit under 35 U.S.C. §119 of Korean Patent Application No. 10-2006-0081967, filed Aug. 28, 2006, the subject matter of which is hereby incorporated by reference in its entirety.

### BACKGROUND

Inductors are commonly used as RF passive elements to generate high frequencies in semiconductor devices. Inductors are often fabricated into a three-dimensional micro-electro mechanical system (MEMS) structure. MEMS is a micro-machining technology for fabricating micro-sized objects in application fields, such as three-dimensional micro-structures, various types of sensors and actuators, precision instruments, and micro-robots, which cannot be fabricated through typical machining processes. In MEMS, a silicon micromachining technology and an integrated circuit fabrication technology are often employed together, allowing micro-sized, highly-integrated inductors to be produced. This allows low-priced and high-performance inductors to be implemented.

A typical RF inductor of a semiconductor device is disclosed in Korean Patent Application Publication No. 2005-0043265 (the '265 application), entitled “Fabrication method of RF inductor of semiconductor device”.

According to the '265 application, an inductor is formed in the shape of a coil, and the inductor includes a copper interconnection.

However, in the method of the '265 application, when patterning an inductor including a copper interconnection through a wet etching process, an insulating layer is often damaged by an etchant. Additionally, copper ions contained in the copper interconnection typically diffuse into the damaged portion of the insulating layer, thereby degrading the performance of the inductor considerably.

Thus, there exists a need in the art for an improved RF inductor and fabricating method thereof.

### BRIEF SUMMARY

Embodiments of the present invention provide an RF inductor and fabricating method thereof.

According to an embodiment, first and second interlayer dielectric layers having different etching selectivity are formed on an insulating layer and a lower metal interconnection. A via hole for exposing the lower metal interconnection is formed in the first and second interlayer dielectric layers, and a trench having a spiral shape is formed. A TiSiN layer on an inner wall of the trench covers an undercut formed at a boundary between the first and second interlayer dielectric layers. A copper interconnection is then formed in the trench and the via hole.

An RF inductor according to an embodiment of the present invention includes: a substrate having a lower metal interconnection; a first interlayer dielectric layer on the substrate and exposing a portion of the lower metal interconnection through a via hole; a second interlayer dielectric layer on the first interlayer dielectric layer and having an etching selectivity different from that of the first interlayer dielectric layer; a via hole through the first and second interlayer dielectric layers and over the lower metal interconnection; a trench at portions of the first and second interlayer dielectric layers and over the via hole; a TiSiN layer formed along inner walls of the via hole and the trench; a copper seed layer formed on the TiSiN layer; and a copper interconnection in the via hole and the trench.

The details of one or more embodiments are set forth in the accompanying drawings and the detailed description below. Other features will be apparent to those skilled in the art from the detailed description, and the drawings, and from the appended claims.

### BRIEF DESCRIPTION OF THE DRAWINGS

FIGS. 1, 2 and 4-7 are cross-sectional views illustrating a fabrication method of an RF inductor in a semiconductor device according to an embodiment of the present invention. FIG. 7 also shows a cross-sectional view of an RF inductor in a semiconductor device according to an embodiment of the present invention.

FIG. 3 is a plan view of a trench formed during a fabrication method of an RF inductor in a semiconductor device according to an embodiment of the present invention.

### DETAILED DESCRIPTION

When the terms “on” or “over” are used herein, when referring to layers, regions, patterns, or structures, it is understood that the layer, region, pattern or structure can be directly on another layer or structure, or intervening layers, regions, patterns, or structures may also be present. When the terms “under” or “below” are used herein, when referring to layers, regions, patterns, or structures, it is understood that the layer, region, pattern or structure can be directly under the other layer or structure, or intervening layers, regions, patterns, or structures may also be present.

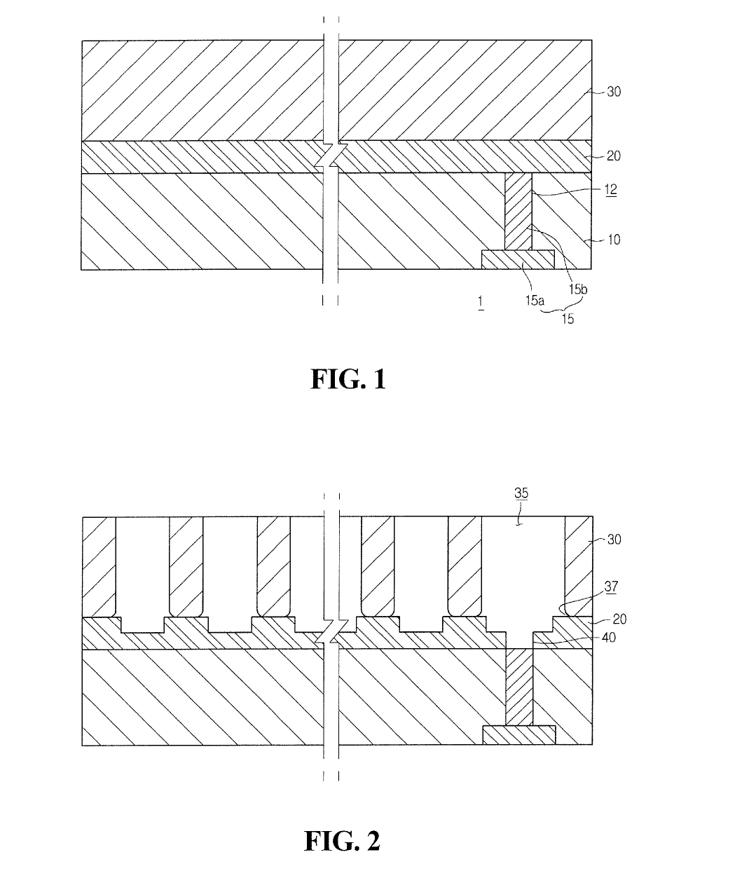

Referring to FIG. 1, an insulating layer 10 and a lower metal interconnection 15, which can be connected to an output terminal of the RF inductor, can be formed on a substrate 1.

In an embodiment, a first lower metal interconnection 15a can be formed on the substrate 1, and the insulating layer 10 covering the first lower metal interconnection 15a can then be formed on the substrate 1. The insulating layer 10 can include any reasonable material known in the art for insulating layers, such as an oxide layer, a nitride layer, or both.

A contact hole 12 for exposing the first lower metal interconnection 15a can be formed, and a second lower metal interconnection 15b can be formed in the contact hole 12. Here, the first lower metal interconnection 15a and the second lower metal interconnection 15b can be used to realize the metal interconnection 15.

Then, a first interlayer dielectric layer 20 can be formed on the insulating layer 10, and a second interlayer dielectric layer 30 can be formed on the first interlayer dielectric layer 20. In an embodiment, the first interlayer dielectric layer 20 can include, a fluorinated silica glass (FSG) layer. The second interlayer dielectric layer 30 can include, for example, an oxide layer.

In an embodiment, the second interlayer dielectric layer 30 is thicker than the first interlayer dielectric layer 20. The second interlayer dielectric layer 30 can be formed thick enough to allow for a thick copper interconnection to be formed.

In an embodiment, the second interlayer dielectric layer 30 has a higher etching selectivity than the first interlayer dielectric layer 20.

Referring to FIG. 2, after forming the second interlayer dielectric layer 30, a first photoresist film (not shown) can be formed on the second interlayer dielectric layer 30 such that the first photoresist film is not over the second lower metal interconnection 15a. The first photoresist film can then be patterned through an exposure and development process, thereby forming a first photoresist pattern (not shown) on the second interlayer dielectric layer 30.

The first photoresist pattern can have an opening over the second lower metal interconnection 15b.

Then, the first interlayer dielectric layer 20 and the second interlayer dielectric layer 30 can be patterned using the first photoresist pattern as an etching mask, thereby forming a via hole 40 passing through the first interlayer dielectric layer 20 and the second interlayer dielectric layer 30.

The first photoresist pattern can be removed, and a second photoresist pattern (not shown) can then be formed on the second interlayer dielectric layer 30. The second photoresist pattern can be formed by forming a second photoresist film and patterning it through an exposure and development process.

The second interlayer dielectric layer 30 and a portion of the first interlayer dielectric layer 20 can be etched using the second photoresist pattern as an etching mask, thereby forming a trench 35. In an embodiment, the etching can be wet etching, reactive ion etching (RIE), or both.

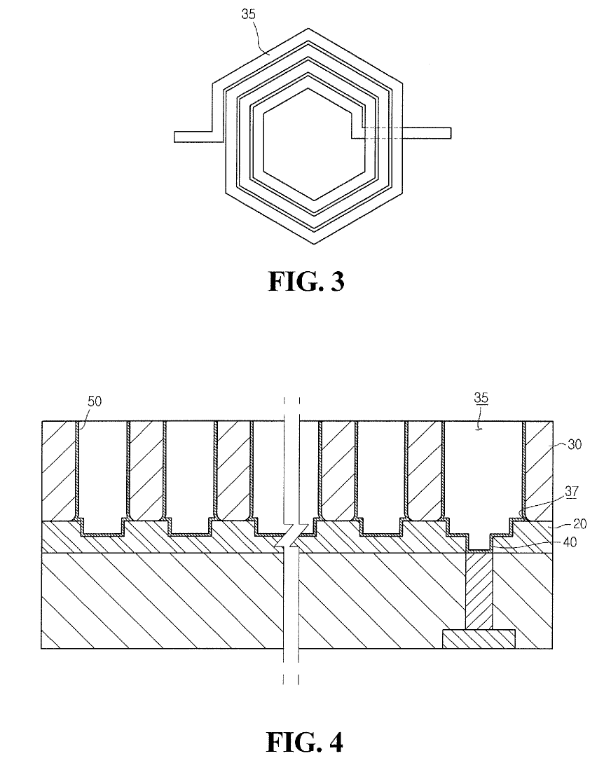

Referring to FIG. 3, the trench 35 can have a spiral or coil shape. The trench 35 can be formed to be long and wound in a spiral shape. The via hole 40 formed in the trench 35 can be over the second lower metal interconnection 15b.

The width of the trench 35 can be larger than the width of the via hole 40.

In many embodiments, when forming the trench 35, an undercut 37 can be formed at the boundary between the first interlayer dielectric layer 20 and the second interlayer dielectric layer 30 due to the different etching selectivity between the first interlayer dielectric layer 20 and the second interlayer dielectric layer 30. A copper interconnection for forming an inductor can be formed in the trench 35 in a spiral shape. It is possible that copper ions contained in the copper interconnection may penetrate into the first interlayer dielectric layer 20 and the second interlayer dielectric layer 30 through the undercut 37. This can lead to a significant reduction the electrical characteristics of the copper interconnection are remarkably reduced.

In order to solve this potential problem, a TiSiN layer 50 can be formed in the trench 35.

The TiSiN layer 50 inhibits diffusion of the copper ions contained in the copper interconnection and covers the undercut 37 as well.

In order to form the TiSiN layer 50, a TiCNH layer that is a first medium layer can be formed on the inner wall of the trench 35 by reacting TrakisDiMethylAmidoTitanium (TDMAT, Ti[N(CH₃)₂]₄) through a chemical vapor deposition (CVD) method.

The TiCNH layer can be reacted using plasma under a hydrogen and nitrogen atmosphere, thereby forming a TiN layer that is a second medium layer on the inner wall of the trench 35. In an embodiment, the TiCNH layer can be reacted with oxygen using plasma. In an embodiment, the TiCNH layer can be reacted using oxygen and nitrogen using plasma.

Then, after forming the TiN layer, a silicon compound, such as SiH₄, can be provided to react with the TiN layer, thereby forming the TiSiN layer 50 in the trench 35. In an embodiment, portions coming into contact with the second lower metal interconnection 15b in the TiSiN layer 50 can be partially etched and removed.

The TiSiN layer 50 on the inner wall of the trench 35 and on the undercut 37 can inhibit copper ions from the copper interconnection from diffusing through the undercut 37.

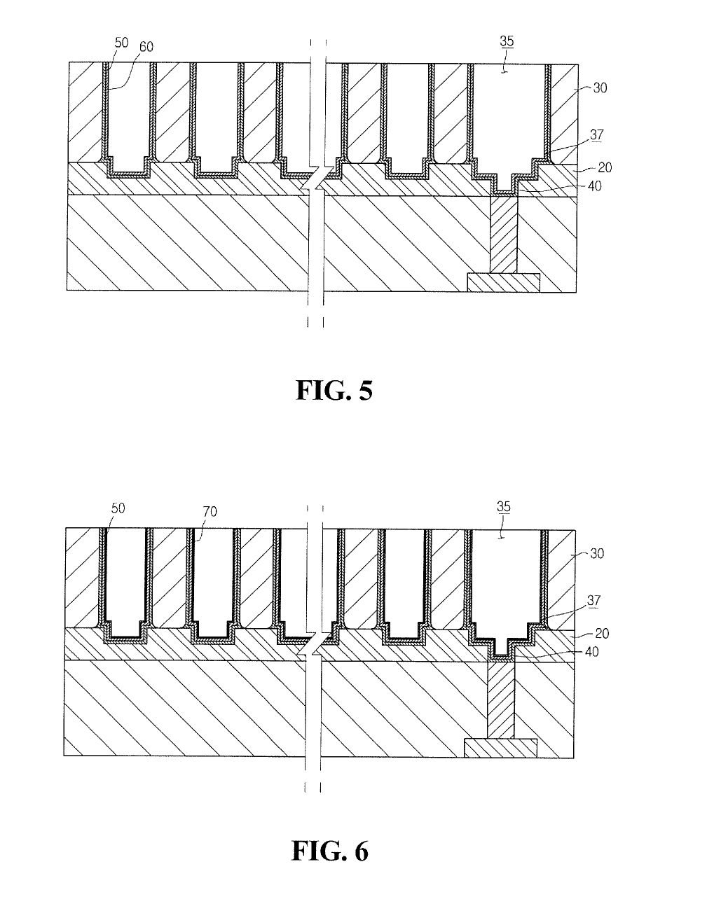

Referring to FIG. 5, after depositing the TiSiN layer 50 on the inner wall of the trench 35, a copper diffusion barrier 60 can be formed on the TiSiN layer 50.

The copper diffusion barrier 60 can include a TaN/Ta double layer. The copper diffusion barrier 60 helps inhibit copper ions of the copper interconnection from diffusing through the TiSiN layer 50. In an embodiment, the copper diffusion barrier 60 is a Ta layer, and the electric mobility of the copper diffusion barrier 60 is superior to that of the TiSiN layer 50. This can lead to enhanced electrical characteristics of the copper interconnection.

Referring to FIG. 6, a copper seed layer 70 can be formed on the copper diffusion barrier 60.

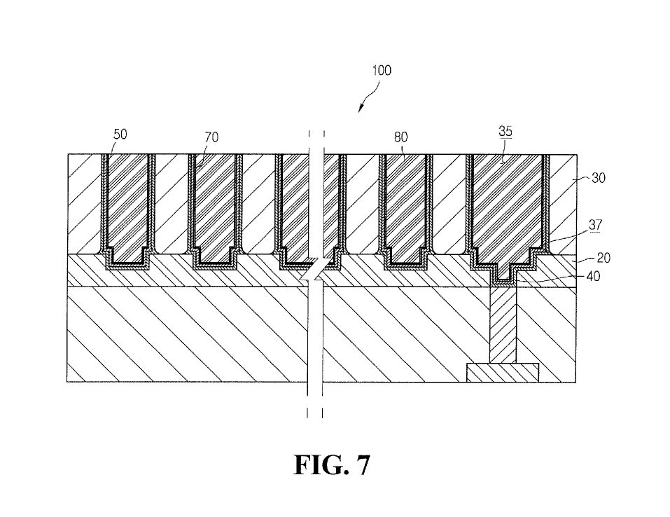

Referring to FIG. 7, after forming the copper seed layer 70 on the copper diffusion barrier 60, a copper interconnection 80 can be formed in the trench 35, thereby forming an RF inductor 100.

When a trench in an inductor has a spiral or coil shape in interlayer dielectric layers, an undercut or void may be produced at the boundary of the interlayer dielectric layers due to a difference in etching selectivity between the interlayer dielectric layers. A TiSiN layer can be formed in the inner wall of the trench to completely cover the undercut. Accordingly, copper ions contained in a copper interconnection in the trench can be inhibited from diffusing through the undercut.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of fabricating an RF inductor of a semiconductor device, comprising:
forming a lower metal interconnection on a substrate;
forming an insulating layer on the substrate;
forming a first interlayer dielectric layer on the insulating layer;
forming a second interlayer dielectric layer on the first interlayer dielectric layer;
forming a via hole over the lower metal interconnection in the first interlayer dielectric layer and the second interlayer dielectric layer;
performing wet and reactive ion etching processes with respect to the second interlayer dielectric layer to form a trench for an inductor, wherein at least a portion of the trench is over the via hole;
forming a TiSiN layer on the trench and via hole;
forming a copper seed layer on the TiSiN layer; and
depositing copper on the copper seed layer to form a copper interconnection in the trench and the via hole.

2. The method according to claim 1, wherein the forming the TiSiN layer comprises:
depositing a TiCNH layer on the trench through a chemical vapor deposition method using TDMAT;
reacting the TiCNH layer with oxygen and/or nitrogen using plasma to form a TiN layer on the trench and via hole; and
treating the TiN layer with SiH₄.

3. The method according to claim 1, further comprising forming a diffusion barrier on the TiSiN layer.

4. The method according to claim 3, wherein the diffusion barrier comprises Ta.

5. The method according to claim 1, wherein the first interlayer dielectric layer comprises an FSG layer, and wherein the second interlayer dielectric layer comprises an oxide layer.

6. The method according to claim 1, wherein the second interlayer dielectric layer is thicker than the first interlayer dielectric layer.

7. The method according to claim 1, wherein the second interlayer dielectric layer has a different etching selectivity than the first interlayer dielectric layer.

8. The method according to claim 1, wherein the trench has a spiral shape.

9. The method according to claim 1, wherein an undercut is formed at a boundary between the first interlayer dielectric layer and the second interlayer dielectric layer by the formation of the trench, and wherein the TiSiN layer covers the undercut.

10. The method according to claim 1, wherein the trench is wider than the via hole.

11. An RF inductor of a semiconductor device, comprising:
a lower metal interconnection on a substrate;
a first interlayer dielectric layer on the substrate and exposing a portion of the lower metal interconnection through a via hole;
a second interlayer dielectric layer on the first interlayer dielectric layer;
a trench in the second interlayer dielectric layer and a portion of the first interlayer dielectric layer, wherein at least a portion of the trench is over the via hole;
a TiSiN layer on an inner wall of the via hole and an inner wall of the trench; and
a copper interconnection on the TiSiN layer in the via hole and the trench;

12. The RF inductor according to claim 11, wherein the trench has a spiral shape.

13. The RF inductor according to claim 11, further comprising an undercut at a boundary between the first interlayer dielectric layer and the second interlayer dielectric layer, wherein the TiSiN layer covers the undercut.

14. The RF inductor according to claim 11, wherein the second interlayer dielectric layer is thicker than the first interlayer dielectric layer.

15. The RF inductor according to claim 11, wherein the second interlayer dielectric layer has a different etching selectivity than the first interlayer dielectric layer.

16. The RF inductor according to claim 11, wherein the trench is wider than the via hole.

17. The RF inductor according to claim 11, further comprising a diffusion barrier on the TiSiN layer.

18. The RF inductor according to claim 17, wherein the diffusion barrier comprises Ta.

19. The RF inductor according to claim 18, wherein the diffusion barrier comprises a TaN/Ta double layer.

20. The RF inductor according to claim 11, wherein the first interlayer dielectric layer comprises an FSG layer, and wherein the second interlayer dielectric layer comprises an oxide layer.
